(19) United States
(12) Patent Application Publication
(10) Pub. No.: US 2005/0006773 A1
(43) Pub. Date: Jan. 13, 2005

(54) Semiconductor device and method for fabricating the same

(75) Inventor: Tsukasa Hattori, Osaka (JP)

Correspondence Address: Jack Q. Lever, Jr.;McDERMOTT, WILL & EMERY LLP, 600 Thirteenth Street, N.W., Washington, DC, 20005-3096, US

(73) Assignee: MATSUSHITA ELECTRIC INDUSTRIAL CO., LTD.

(21) Appl. No.: 10/884,998

(22) Filed: Jul. 7, 2004

(30) Foreign Application Priority Data
Jul. 7, 2003 (JP) 2003-192675

(51) Int. Cl. H01L 29/00

(52) U.S. Cl. 257/758

(57) ABSTRACT

A semiconductor device has a first metal pattern made of a first metal formed on a semiconductor substrate, an insulating film formed over the first metal pattern, and a second metal pattern made of a second metal formed on the insulating film. The insulating film has a barrier property for preventing the diffusion of the first metal.

### BACKGROUND OF THE INVENTION

The present invention relates to a semiconductor device and a method for fabricating the same and, more particularly, to an antifuse structure used in an FPGA (Field Programmable Gate Array) element as a reconfigurable logic device and a method for fabricating the same.

Referring to FIGS. 9A to 9F, a description will be given herein below to a method for fabricating a semiconductor device related to a prior art technology, specifically to a method for fabricating an antifuse.

FIGS. 9A to 9F are cross-sectional views illustrating the principal steps of the method for fabricating the semiconductor device related to the prior art technology.

First, as shown in FIG. 9A, a wiring layer 110a made of a metal material such as aluminum is deposited on a semiconductor substrate 100. The wiring layer 110a may also have a structure in which layers made of a metal material represented by titanium or a titanium nitride are deposited on and under an aluminum layer. Subsequently, a first insulating film 102 made of amorphous silicon or the like and having an antifusing function is deposited over the wiring layer 110a.

Next, as shown in FIG. 9B, the wiring layer 110a and the first insulating film 102 are patterned by a lithographic process and an etching process to form a wire 101.

Next, as shown in FIG. 9C, a second insulating film 103 is formed on the semiconductor substrate 100 in such a manner as to cover the wire 101 composed of the patterned wiring layer 110a and the patterned first insulating film 102.

Next, as shown in FIG. 9D, the second insulating film 103 is etched to form a first via 104 and a second via 105 each reaching the upper surface of the first insulating film 102. It is to be noted that the first insulating film 102 having the antifusing function is exposed at the respective bottom portions of the first and second vias 104 and 105.

Next, as shown in FIG. 9E, a resist pattern 106 is formed such that only the second via 105 formed in an antifuse formation region 9B is covered therewith. Subsequently, the portion of the first insulating film 102 located at the bottom portion of the first via 104 is etched away by using the resist pattern 106 as a mask such that the first via 104 formed in a circuit formation region 9A is connected to the wire 101. Thereafter, the resist pattern 106 is removed.

Next, as shown in FIG. 9F, a metal material is filled in each of the first and second vias 104 and 105 by using CVD and CMP techniques and the like, thereby forming a first via plug 107 and a second via plug 108.

By the foregoing process, an antifuse 109 is formed in the antifuse formation region 9B (see, e.g., Japanese Laid-Open Patent Publication No. HEI 6-97171).

In accordance with the method for fabricating a semiconductor device according to the prior art technology, however, it is required to perform at least the step of forming the first insulating film 102 having the antifusing function even in the region other than the antifuse formation region 9B, i.e., in the circuit formation region 9A. Accordingly, the number of steps is increased disadvantageously in the circuit formation region 9A compared with that of the process which does not use an antifuse structure, i.e., the process which does not form the first insulating film 102 having the antifusing function. This leads to the problem of higher process cost and also the problem of a potential reduction in yield which may be caused by increased particles resulting from an increased number of steps. There is also another problem that the patterning of a multilayer structure composed of the first insulating film 102 having the antifusing function and the wire 101 in the circuit formation region 9A is extremely difficult compared with the case where only the wire 101 is patterned. Still another problem is that defective filling of the second insulating film 103 may form a void 103a between the first insulating film 102 having the antifusing function in the antifuse formation region 9B and the wire 101 in the circuit formation region 9A, as shown in FIG. 9F.

### SUMMARY OF THE INVENTION

In view of the foregoing, it is therefore an object of the present invention to provide a semiconductor device and a method for fabricating the same which allow a reduction in process cost and an improvement in yield by reducing the number of process steps.

To attain the foregoing object, a first semiconductor device according to the present invention comprises: a first metal pattern made of a first metal formed on a semiconductor substrate; an insulating film formed over the first metal pattern; and a second metal pattern made of a second metal formed on the insulating film, wherein the insulating film has a barrier property for preventing diffusion of the first metal.

The first semiconductor device allows the implementation of an antifuse structure which can be fabricated by using a normal wiring formation process such as a damascene wiring formation process used as, e.g., a copper wiring formation process. As a result, it becomes possible to implement an antifuse structure which can be fabricated in the number of steps smaller than that required by the conventional antifuse formation process. Accordingly, there is provided a semiconductor device which allows a reduction in process cost and an improvement in yield.

In the first semiconductor device according to the present invention, the insulating film preferably contains the diffused first metal.

Since the first metal is contained in the insulating film, the insulating film functions as an antifuse in which a dielectric breakdown can easily be caused by the application of a voltage.

In the first semiconductor device according to the present invention, the second metal pattern is preferably formed in such a manner as to sink into the insulating film.

Since the second metal pattern has thus sunk into the insulating film, the insulating film functions as an antifuse in which a dielectric breakdown can easily be caused by the application of a voltage.

In the first semiconductor device according to the present invention, the first metal pattern is preferably a wire or a via plug.

The arrangement allows the implementation of an antifuse structure which can be fabricated by using a damascene wiring formation process.

In the first semiconductor device according to the present invention, the second metal pattern is preferably a wire or a via plug.

The arrangement allows the implementation of an antifuse structure which can be fabricated by using a damascene wiring formation process. When the second metal pattern is a via plug, an area required to form the antifuse can be reduced.

A second semiconductor device according to the present invention comprises: a first metal pattern made of a first metal formed on a semiconductor substrate; an insulating film formed over the first metal pattern; and a second metal pattern made of a second metal formed on the insulating film, wherein the insulating film has a barrier property for preventing diffusion of the first metal and the second metal pattern is formed in a circuit formation region to extend through the insulating film and be electrically connected to the first metal pattern, while it is formed in an antifuse formation region with the insulating film being interposed between itself and the first metal pattern.

The second semiconductor device allows the implementation of an antifuse structure which can be fabricated by using a normal wiring formation process such as a damascene wiring formation process used as, e.g., a copper wiring formation process. As a result, it becomes possible to implement an antifuse structure which can be fabricated in the number of steps smaller than that required by the conventional antifuse formation process. Accordingly, there is provided a semiconductor device which allows a reduction in process cost and an improvement in yield.

In the second semiconductor device according to the present invention, the insulating film preferably contains the diffused first metal.

Since the first metal is contained in the insulating film, the insulating film functions as an antifuse in which a dielectric breakdown can easily be caused by the application of a voltage.

In the second semiconductor device according to the present invention, the second metal pattern in the antifuse formation region is preferably formed in such a manner as to sink into the insulating film.

Since the second metal pattern has thus sunk into the insulating film, the insulating film functions as an antifuse in which a dielectric breakdown can easily be caused by the application of a voltage.

In the second semiconductor device according to the present invention, the first metal pattern is preferably a wire or a via plug.

The arrangement allows the implementation of an antifuse structure which can be fabricated by using a damascene wiring formation process.

In the second semiconductor device according to the present invention, the second metal pattern is preferably a wire or a via plug.

The arrangement allows the implementation of an antifuse structure which can be fabricated by using a damascene wiring formation process. When the second metal pattern is a via plug, an area required to form the antifuse can be reduced.

A first method for fabricating a semiconductor device according to the present invention comprises the steps of: forming a wire made of a first metal on a semiconductor substrate; forming a first insulating film over the wire; forming a second insulating film on the first insulating film; forming an opening for exposing the first insulating film in each of respective portions of the second insulating film located in a circuit formation region and in an antifuse formation region such that the opening is positioned above the wire after forming a resist pattern such that the opening in the antifuse formation region is covered therewith, performing etching by using the resist pattern as a mask to remove a portion of the first insulating film exposed at a bottom portion of the opening in the circuit formation region and thereby expose the wire; and after removing the resist pattern, burying a second metal in each of the opening in the circuit formation region and the opening in the antifuse formation region to form a metal pattern, wherein the first insulating film has a barrier property for preventing diffusion of the first metal.

In accordance with the first method for fabricating a semiconductor device, etching is performed by masking the opening in the antifuse formation region. This allows the formation of the metal pattern connected electrically to the wire in the circuit formation region, while allowing the formation of a structure in which the first insulating film functions as an antifuse in the antifuse formation region. Thus, an antifuse structure which can be fabricated by using a damascene wiring formation process used as, e.g., a copper wiring formation process is implemented. As a result, it becomes possible to implement an antifuse structure which can be fabricated in the number of steps smaller than that required by the conventional antifuse formation process. Accordingly, there is provided a method for fabricating a semiconductor device which allows a reduction in process cost and an improvement in yield.

A second method for fabricating a semiconductor device according to the present invention comprises the steps of: forming a wire made of a first metal on a semiconductor substrate; forming a first insulating film over the wire; forming a second insulating film on the first insulating film; forming a first opening for exposing the first insulating film in each of respective portions of the second insulating film located in a circuit formation region and in an antifuse formation region such that the opening is positioned above the wire; in forming a resist pattern composed of a positive resist for forming a second opening over the first opening in the antifuse formation region, performing etching by using a remaining portion of the positive resist formed by insufficient exposure as a mask to remove a portion of the first insulating film exposed at a bottom portion of the first opening in the circuit formation region and thereby expose the wire; and after removing the resist pattern, burying a second metal in each of the first opening in the circuit formation region and the first opening in the antifuse formation region to form a metal pattern, wherein the first insulating film has a barrier property for preventing diffusion of the first metal.

In accordance with the second method for fabricating a semiconductor device, etching is performed by using, in masking the first opening in the antifuse formation region, the remaining portion of the positive resist as a mask for forming the second opening which was formed by using insufficient exposure when the resist pattern composed of the positive resist was formed. This allows the formation of the metal pattern connected electrically to the wire in the circuit formation region, while allowing the formation of a structure in which the first insulating film functions as an antifuse in the antifuse formation region. Thus, an antifuse structure which can be fabricated by using a damascene wiring formation process used as, e.g., a copper wiring formation process is implemented. As a result, it becomes possible to implement an antifuse structure which can be fabricated in the number of steps smaller than that required by the conventional antifuse formation process. Accordingly, there is provided a method for fabricating a semiconductor device which allows a reduction in process cost and an improvement in yield.

A third method for fabricating a semiconductor device according to the present invention comprises the steps of: forming a wire made of a first metal on a semiconductor substrate; forming a first insulating film over the wire; performing etching to thin a portion of the first insulating film located in a circuit formation region; after the step of performing the etching, forming a second insulating film on the first insulating film; forming an opening for exposing the wire in a portion of the second insulating film located in the circuit formation region such that the opening is positioned above the wire, while forming an opening for exposing the first insulating film in a portion of the second insulating film located in an antifuse formation region such that the opening is positioned above the wire; and burying a second metal in each of the opening in the circuit formation region and the opening in the antifuse formation region to form a metal pattern, wherein the first insulating film has a barrier property for preventing diffusion of the first metal.

In accordance with the third method for fabricating a semiconductor device, the portion of the first insulating film located in the circuit formation region is thinned, while the portion of the first insulating film located in the antifuse formation region remains thick. This allows the formation of the metal pattern connected electrically to the wire in the circuit formation region, while allowing the formation of a structure in which the first insulating film functions as an antifuse in the antifuse formation region without masking the opening in the antifuse formation region. Thus, an antifuse structure which can be fabricated by using a damascene wiring formation process used as, e.g., a copper wiring formation process is implemented. As a result, it becomes possible to implement an antifuse structure which can be fabricated in the number of steps smaller than that required by the conventional antifuse formation process. Accordingly, there is provided a method for fabricating a semiconductor device which allows a reduction in process cost and an improvement in yield.

A fourth method for fabricating a semiconductor device according to the present invention comprises the steps of: forming a wire made of a first metal on a semiconductor substrate; forming a first insulating film over the wire; forming a second insulating film on the first insulating film; forming a third insulating film on the second insulating film; performing etching to remove a portion of the third insulating film located in a circuit formation region; after the step of performing the etching, forming a fourth insulating film over the second and third insulating films; forming an opening for exposing the wire in each of respective portions of the fourth, second, and first insulating films located in the circuit formation region such that the opening is positioned above the wire, while forming an opening for exposing the first insulating film in each of respective portions of the fourth, third, and second insulating films located in the antifuse formation region such that the opening is positioned above the wire; and burying a second metal in each of the opening in the circuit formation region and the opening in the antifuse formation region to form a metal pattern, wherein the first insulating film has a barrier property for preventing diffusion of the first metal.

In accordance with the fourth method for fabricating a semiconductor device, the portion of the third insulating film located in the antifuse formation region serves as an etching stopper since the portion of the third insulating film located in the circuit formation region is removed. This allows the formation of the metal pattern connected electrically to the wire in the circuit formation region, while allowing the formation of a structure in which the first insulating film functions as an antifuse in the antifuse formation region without masking the opening in the antifuse formation region. Thus, an antifuse structure which can be fabricated by using a damascene wiring formation process used as, e.g., a copper wiring formation process is implemented. As a result, it becomes possible to implement an antifuse structure which can be fabricated in the number of steps smaller than that required by the conventional antifuse formation process. Accordingly, there is provided a method for fabricating a semiconductor device which allows a reduction in process cost and an improvement in yield.

Preferably, in the first to fourth methods for fabricating a semiconductor device according to the present invention, the step of forming the opening is a step of forming a wiring trench or a via hole and the step of forming the metal pattern is a step of forming a wire if the wiring trench is formed in the step of forming the opening, while it is a step of forming a via plug if the via hole is formed in the step of forming the opening.

The arrangement allows the implementation of an antifuse structure which can be fabricated by using a damascene wiring formation process. When the metal pattern is a via plug, an area required to form the antifuse can be reduced.

A fifth method for fabricating a semiconductor device according to the present invention comprises the steps of: forming a via plug made of a first metal on a semiconductor substrate; forming a first insulating film over the via plug; forming a second insulating film on the first insulating film; forming an opening for exposing the first insulating film in each of respective portions of the second insulating film located in a circuit formation region and in an antifuse formation region such that the opening is positioned above the via plug after forming a resist pattern such that the opening formed in the antifuse formation region is covered therewith, performing etching by using the resist pattern as a mask to remove a portion of the first insulating film exposed at a bottom portion of the opening in the circuit formation region and thereby expose the via plug; and after removing the resist pattern, burying a second metal in each of the opening in the circuit formation region and the opening in the antifuse formation region to form a metal pattern, wherein the first insulating film has a barrier property for preventing diffusion of the first metal.

In accordance with the fifth method for fabricating a semiconductor device, etching is performed by masking the opening in the antifuse formation region. This allows the formation of the metal pattern connected electrically to the wire in the circuit formation region, while allowing the formation of a structure in which the first insulating film functions as an antifuse in the antifuse formation region. Thus, an antifuse structure which can be fabricated by using a damascene wiring formation process used as, e.g., a copper wiring formation process is implemented. As a result, it becomes possible to implement an antifuse structure which can be fabricated in the number of steps smaller than that required by the conventional antifuse formation process. Accordingly, there is provided a method for fabricating a semiconductor device which allows a reduction in process cost and an improvement in yield.

Preferably, in the fifth method for fabricating a semiconductor device according to the present invention, the step of forming the opening is a step of forming a wiring trench or a via hole and the step of forming the metal pattern is a step of forming a wire if the wiring trench is formed in the step of forming the opening, while it is a step of forming a via plug if the via hole is formed in the step of forming the opening.

The arrangement allows the implementation of an antifuse structure which can be fabricated by using a damascene wiring formation process. When the metal pattern is a via plug, an area required to form the antifuse can be reduced.

In the first to fifth methods for fabricating a semiconductor device according to the present invention, the first insulating film preferably contains the diffused first metal.

Since the first metal is contained in the first insulating film, the insulating film functions as an antifuse in which a dielectric breakdown can easily be caused by the application of a voltage.

In the first to fifth methods for fabricating a semiconductor device according to the present invention, the metal pattern formed on the first insulating film is preferably formed in such a manner as to sink into the insulating film.

Since the metal pattern has thus sunk into the insulating film, the insulating film functions as an antifuse in which a dielectric breakdown can easily be caused by the application of a voltage.

### BRIEF DESCRIPTION OF THE DRAWINGS

FIG. 1 is a cross-sectional view of a principal portion of a semiconductor device having an antifuse structure according to a first embodiment of the present invention;

FIG. 2 is a cross-sectional view of a principal portion of a semiconductor device having an antifuse structure according to the first embodiment;

FIG. 3 is a cross-sectional view of a principal portion of a semiconductor device having an antifuse structure according to a second embodiment of the present invention;

FIGS. 4A to 4E are cross-sectional views illustrating the principal steps of a method for fabricating a semiconductor device having an antifuse structure according to a third embodiment of the present invention;

FIGS. 5A to 5E are cross-sectional views illustrating the principal steps of a method for fabricating a semiconductor device having an antifuse structure according to a fourth embodiment of the present invention;

FIGS. 6A to 6E are cross-sectional views illustrating the principal steps of a method for fabricating a semiconductor device having an antifuse structure according to a fifth embodiment of the present invention;

FIGS. 7A to 7F are cross-sectional views illustrating the principal steps of a method for fabricating a semiconductor device having an antifuse structure according to a sixth embodiment of the present invention;

FIGS. 8A to 8E are cross-sectional views illustrating the principal steps of a method for fabricating a semiconductor device having an antifuse structure according to a seventh embodiment of the present invention; and

FIGS. 9A to 9F are cross-sectional views illustrating the principal steps of a method for fabricating a conventional semiconductor device having an antifuse structure.

### DETAILED DESCRIPTION OF THE INVENTION

Referring to the drawings, the individual embodiments of the present invention will be described herein below.

Embodiment 1

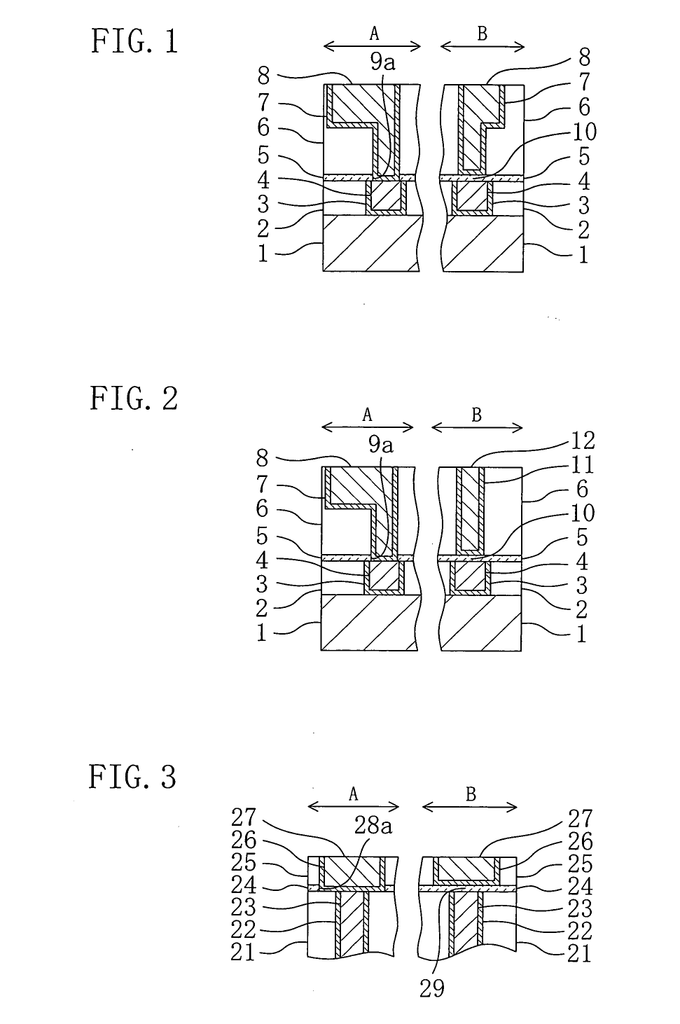

A semiconductor device having an antifuse structure according to the first embodiment of the present invention will be described with reference to FIGS. 1 and 2.

FIG. 1 is a cross-sectional view showing a principal portion of the semiconductor device having the antifuse structure according to the first embodiment. In FIG. 1, a circuit formation region A and an antifuse formation region B are shown.

As shown in FIG. 1, a first insulating film 2 is formed on a semiconductor substrate 1. The first insulating film 2 is formed with first wires (first metal pattern) 4 each made of, e.g., copper and having a first barrier film 3. A second barrier film 5 is formed over the first insulating film 2 and the first wire 4. The second barrier film 5 has the function of preventing the diffusion of a metal composing the first wire 4 and serves herein as a diffusion preventing film for preventing the diffusion of copper. A second insulating film 6 is formed on the second barrier film 5. The second insulating film 6 is formed with second wires (second metal pattern) 8 each made of, e.g., copper and having a third barrier film 7.

In the circuit formation region A, the second wire 8 with the third barrier film 7 is connected to the first wire 4 via a connection hole 9a formed to extend through the second barrier film 5. In the antifuse formation region B, no connection hole is provided in the second barrier film 5 so that the second wire 8 with the third barrier film 7 has the second barrier film 5 interposed between itself and the first wire 4 with the first barrier film 3.

Thus, in the antifuse formation region B, the second barrier film 5 as a diffusion preventing film for preventing the diffusion of copper composing the first wire 4 is formed with an antifuse 10, so that the antifuse 10 traps the metal diffused from the first wire 4. Accordingly, the antifuse 10 can be used as an antifuse in which a dielectric breakdown can easily be caused by the application of a voltage. In the first embodiment in which the first wire 4 is made of copper, copper is diffused particularly easily into the second barrier film 5. This allows the use of the antifuse 10 as an easier antifuse.

FIG. 2 shows a variation of the structure of the semiconductor device shown in FIG. 1. In FIG. 2, the same components as shown in FIG. 1 are designated by the same reference numerals. Herein below, a description will be given primarily to features different from those shown in FIG. 1.

In the semiconductor device shown in FIG. 2, a via plug (second metal pattern) 12 made of, e.g., copper and having a third barrier film 11 is formed on the second barrier film 5 in the antifuse formation region B. The semiconductor device shown in FIG. 2 is different from that shown in FIG. 1 in that the second wire 8 is formed in the antifuse formation region B.

By thus forming the via plug 12 above the second barrier film 5, an area required for the formation of the antifuse 10 can be reduced.

In addition, the use of a silicon nitride film (SiN) or silicon carbon (SiC) for the second barrier film 5 shown in FIGS. 1 and 2 enhances the effect of preventing the diffusion of copper composing the first wires 4. The resultant antifuse 10 allows the setting of the applied voltage which causes a dielectric breakdown to a high value.

It is preferred that, in the antifuse formation region B, the second barrier film 5 has a thickness smaller than that when it was formed first and is therefore lower in level, and the second wire 8 shown in FIG. 1 or the via plug 12 shown in FIG. 2 is formed in such a manner as to sink into the portion lower in level. In such a structure, a dielectric breakdown is more likely to occur in the portion of the second barrier film 5 which is lower in level. Accordingly, the antifuse 10 can be used as an antifuse in which a dielectric breakdown is easily caused by the application of a voltage.

Although the present embodiment has described the case where a material used for the wires or via plug is copper, the present invention is also practicable even when a noble metal such as gold or silver is used also as a material instead of copper.

Embodiment 2

A semiconductor device having an antifuse structure according to the second embodiment of the present invention will be described with reference to FIG. 3.

FIG. 3 is a cross-sectional view showing a principal portion of the semiconductor device having the antifuse structure according to the second embodiment

As shown in FIG. 3, via plugs (first metal pattern) 23 each made of, e.g., copper and having a first barrier film 22 is formed on a first insulating film 21 formed on, e.g., a semiconductor substrate (not shown). A second barrier film 24 is formed over the first insulating film 21 and the via plug 23. The second barrier film 24 has a function as a diffusion preventing film for preventing the diffusion of a metal composing the via plugs 23 so that it serves herein as a diffusion preventing film against copper. A second insulating film 25 is formed on the second barrier film 24. The second insulating film 25 is formed with wires (second metal pattern) 27 each made of, e.g., copper and having a third barrier film 26.

In the circuit formation region A, the wire 27 with the third barrier film 26 is connected to the via plug 23 via a connection hole 28a formed by removing the second barrier film 24. In the antifuse formation region B, no connection hole is provided in the second barrier film 24 so that the wire 27 with the third barrier film 26 has the second barrier film 24 interposed between itself and the via plug 23 with the first barrier film 22.

Thus, in the antifuse formation region B, the second barrier film 24 as a film for preventing the diffusion of copper composing the via plug 23 is formed with an antifuse 29, so that the antifuse 29 traps the metal diffused from the via plug 23. Accordingly, the antifuse 29 can be used as an antifuse in which a dielectric breakdown can easily be caused by the application of a voltage. In the present embodiment in which the via plug 23 is made of copper, copper is diffused particularly easily into the second barrier film 24. This allows the use of the antifuse 29 as an easier antifuse.

Although the present embodiment has described the case where the wire 27 is formed above the antifuse 29, there may also be used a structure in which a via plug (not shown) is formed above the antifuse 29 in the same manner as in the foregoing first embodiment.

By thus forming the via plug above the second barrier film 24, an area required for the formation of the antifuse can be reduced.

In addition, the use of a silicon nitride film (SiN) or silicon carbon (SiC) for the second barrier film 24 shown in FIG. 3 enhances the effect of preventing the diffusion of copper composing the via plugs 23. The resultant antifuse 29 allows the setting of the applied voltage which causes a dielectric breakdown to a high value.

It is preferred that, in the antifuse formation region B, the second barrier film 24 has a thickness smaller than that when it was formed first and is therefore lower in level, and the wire 27 shown in FIG. 3 or the via plug formed in place of the wire 27 is formed in such a manner as to sink into the portion lower in level. In such a structure, a dielectric breakdown is more likely to occur in the portion of the second barrier film 24 which is lower in level. Accordingly, the antifuse 29 can be used as an antifuse in which a dielectric breakdown is easily caused by the application of a voltage.

Although the present embodiment has described the case where a material used for the wires or via plugs is copper, the present invention is also practicable even when a noble metal such as gold or silver is used also as a material instead of copper.

Embodiment 3

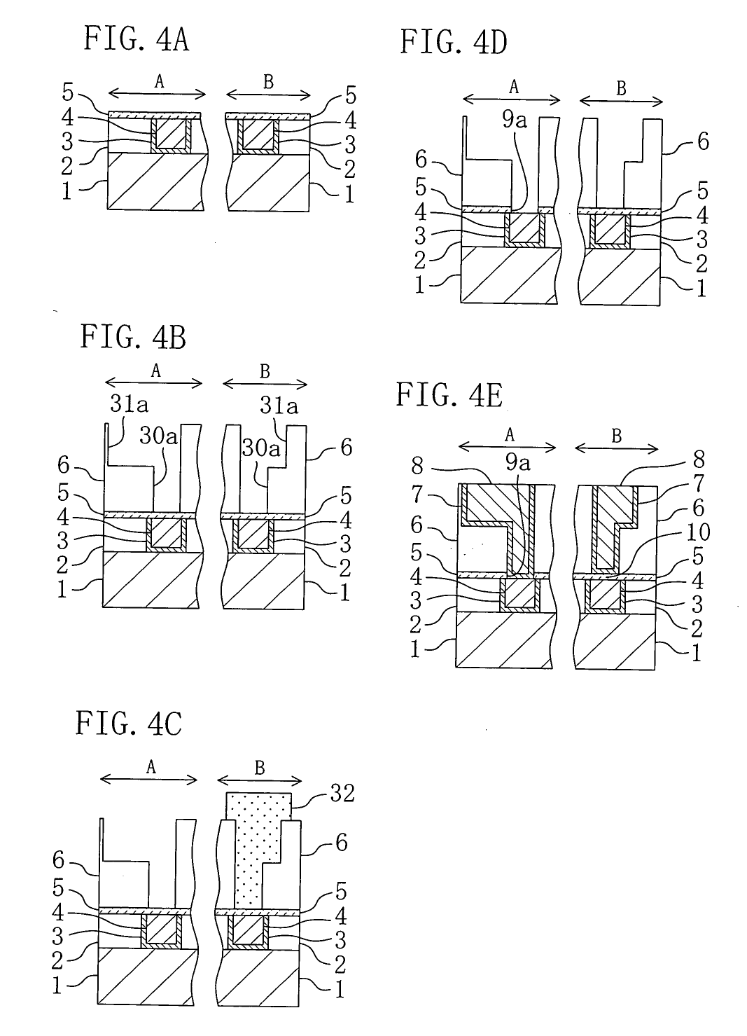

A method for fabricating a semiconductor device having an antifuse structure according to the third embodiment of the present invention will be described with reference to FIGS. 4A to 4E.

FIGS. 4A to 4E are cross-sectional views illustrating the principal steps of the method for fabricating a semiconductor device having an antifuse structure according to the third embodiment. In FIG. 4, the components common to those shown in FIG. 1 are designated by the same reference numerals.

First, as shown in FIG. 4A, the first insulating film 2 is formed on the semiconductor substrate 1 and then the first wire 4 made of, e.g., copper and having the first barrier film 3 is formed on the first insulating film 2. Subsequently, the second barrier film 5 is formed over the first insulating film 2 and the first wire 4. The second barrier film 5 functions as a diffusion preventing film for preventing the diffusion of the metal composing the first wire 4 so that it serves herein as a diffusion preventing film against copper. The second barrier film 5 also serves as an etching stopper during the formation of upper-layer vias.

Next, as shown in FIG. 4B, the second insulating film 6 is formed on the second barrier film 5. Then, vias 30a and trenches 31a are formed in the second insulating film 6. Alternatively, the second insulating film 6 may also be formed as a plurality of layers of different types. It is also possible to perform a planarization process using a CMP technology or the like if a process for reducing a level difference is required as in the case of, e.g., forming an insulating film over an underlying wire.

Next, as shown in FIG. 4C, a resist pattern 32 is formed in such a manner as to cover the via 30a not to be connected to the first wire 4 as a lower-layer wire in the antifuse formation region B, while leaving the via 30a to be connected to the first wire 4 as the lower-layer wire exposed in the circuit formation region A.

Next, as shown in FIG. 4D, etching is performed by using the resist pattern 32 as a mask, thereby forming the connection hole 9a reaching the first wire 4 in the second barrier film 5 in the circuit formation region A. As a result, the via 30a is connected to the first wire 4 as the lower-layer wire in the circuit formation region A. Then, the resist pattern 32 is removed.

Next, as shown in FIG. 4E, the second wire 8 made of, e.g., copper and having the third barrier film 7 is formed in each of the connection hole 9a, the via 30a, and the trench 31a in the circuit formation region A, while it is formed in each of the via 30a and the trench 31a in the antifuse formation region B. The second wire 8 can be formed by burying a metal material (which is, e.g., copper herein) by using a sputtering, CVD, or plating technology or the like and then removing the unwanted portion thereof by using a CMP technology.

Since no connection hole is thus provided in the second barrier film 5 in the antifuse formation region B, the second wire (metal pattern) 8 having the third barrier film 7 has the second barrier film 5 interposed between itself and the first wire 4 with the first barrier film 3. That is, in the antifuse formation region B, the antifuse 10 is formed in the second barrier film 5 as a film for preventing the diffusion of copper composing the first wire 4, which is located in a layer underlying the second wire 8 not to be connected to the first wire 4.

Thus, according to the embodiment of the present invention, the antifuse 10 can be formed by using a damascene process as a normal wiring formation process, which is represented by, e.g., a copper wiring formation process. This achieves a reduction in the number of required steps compared with that of the conventional antifuse formation process, a reduction in cost, and an improvement in yield.

Although the present embodiment has not particularly described the order in which the vias 30a and the trenches 31a are formed, either of the vias 30a and the trenches 31a may be formed earlier.

Although the present embodiment has described the case where the second wire 8 formed above the antifuse 10 is composed of the metal material buried in the via 30 and the trench 31a, the antifuse 10 can also be formed even in the case where only the via 30a is formed without forming the trench 31a and only the via plug is formed above the antifuse 10. In that case, the area required for the formation of the antifuse 10 can be reduced.

In addition, the use of a silicon nitride film (SiN) or silicon carbon (SiC) for the second barrier film 5 in the present embodiment enhances the effect of preventing the diffusion of copper composing the first wire 4. The resultant antifuse 10 allows the setting of the applied voltage which causes a dielectric breakdown to a high value.

It is preferred that, in the antifuse formation region B, the second barrier film 5 has a thickness smaller than that when it was formed first and is therefore lower in level, and the second wire 8 is formed in such a manner as to sink into the portion lower in level. In such a structure, a dielectric breakdown is more likely to occur in the portion of the second barrier film 5 which is lower in level. Accordingly, the antifuse 10 can be used as an antifuse in which a dielectric breakdown is easily caused by the application of a voltage.

Although the present embodiment has described the case where a material used for the wires or via plug is copper, the present invention is also practicable even when a noble metal such as gold or silver is used also as a material instead of copper.

Embodiment 4

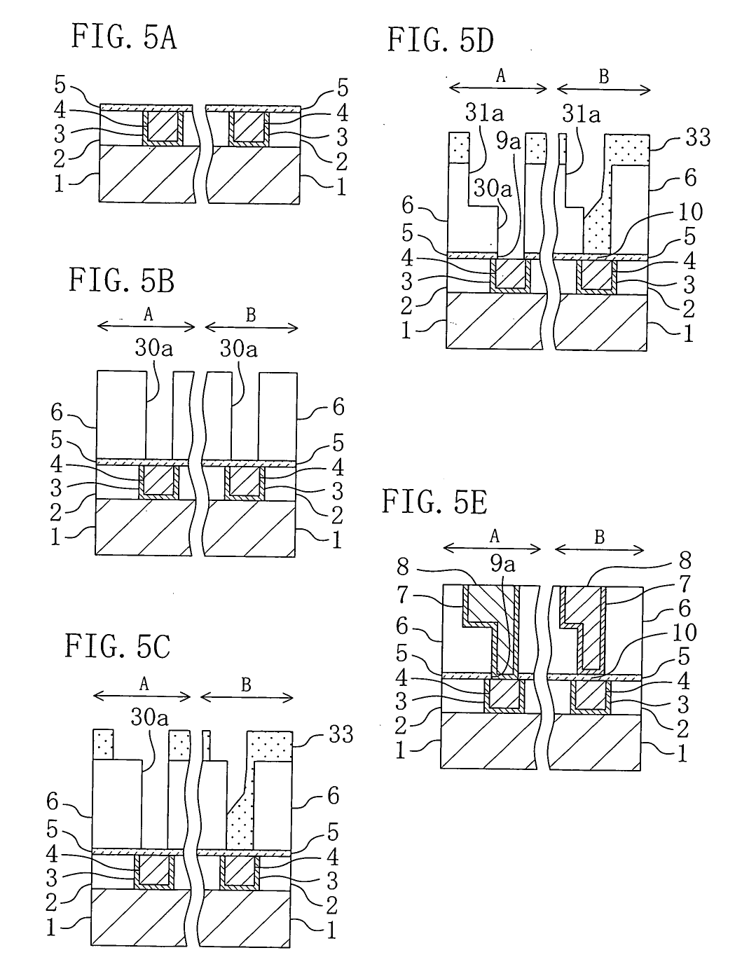

A method for fabricating a semiconductor device having an antifuse structure according to the fourth embodiment of the present invention will be described with reference to FIGS. 5A to 5E.

FIGS. 5A to 5E are cross-sectional views illustrating the principal steps of the method for fabricating a semiconductor device having an antifuse structure according to the fourth embodiment. In FIGS. 5A to 5E, the components common to those shown in FIG. 1 are designated by the same reference numerals.

First, as shown in FIG. 5A, the first insulating film 2 is formed on the semiconductor substrate 1 and then the first wires 4 each made of, e.g., copper and having the first barrier film 3 is formed on the first insulating film 2. Subsequently, the second barrier film 5 is formed over the first insulating film 2 and the first wires 4. The second barrier film 5 functions as a diffusion preventing film for preventing the diffusion of the metal composing the first wires 4 so that it serves herein as a diffusion preventing film against copper. The second barrier film 5 also serves as an etching stopper during the formation of upper-layer vias.

Next, as shown in FIG. 5B, the second insulating film 6 is formed on the second barrier film 5. Then, the vias 30a are formed in the second insulating film 6. Alternatively, the second insulating film 6 may also be formed as a plurality of layers of different types. It is also possible to perform a planarization process using a CMP technology or the like if a process for reducing a level difference is required as in the case of, e.g., forming an insulating film over an underlying wire.

Next, as shown in FIG. 5C, a resist pattern 33 is formed by using a positive resist material in such a manner as to cover the via 30a not to be connected to the first wire 4 as a lower-layer wire in the antifuse formation region B, while leaving the via 30a to be connected to the first wire 4 as the lower-layer wire exposed in the circuit formation region A. At this time, the resist pattern 33 is formed such that the trench formed over the via 30a not to be connected to the first wire 4 has a pattern width equal to the width of the via 30a.

Alternatively, the resist pattern 33 is formed by placing a resist pattern for forming the trench such that one-half or more of the via 30a is covered with the positive resist material and thereby causing an insufficient dose in the via 30a so that the remaining portion of the positive resist material forms the resist pattern 33. The trench is formed herein to have a pattern width larger than the pattern width of the via by 0.2 μm.

Next, as shown in FIG. 5D, etching is performed by using the resist pattern 33 as a mask, thereby forming trenches 31a. Meanwhile, the connection hole 9a is formed in the second barrier film 5 in the circuit formation region A to extend therethrough and reach the first wire 4. As a result, the via 30a is connected to the first wire 4 as the lower-layer wire in the circuit formation region A. Then, the resist pattern 33 is removed.

Next, as shown in FIG. 5E, the second wire (metal pattern) 8 made of, e.g., copper and having the third barrier film 7 is formed in each of the connection hole 9a, the via 30a, and the trench 31a in the circuit formation region A, while it is formed in each of the via 30a and the trench 31a in the antifuse formation region B. The second wire 8 can be formed by burying a metal material (which is, e.g., copper herein) by using a sputtering, CVD, or plating technology or the like and then removing the unwanted portion thereof by using a CMP technology.

Since no connection hole is thus provided in the second barrier film 5 in the antifuse formation region B, the second wire 8 having the third barrier film 7 has the second barrier film 5 interposed between itself and the first wire 4 with the first barrier film 3. That is, in the antifuse formation region B, the antifuse 10 is formed in the second barrier film 5 as a film for preventing the diffusion of copper composing the first wire 4, which is located in a layer underlying the second wire 8 not to be connected to the first wire 4.

Thus, in the method for fabricating a semiconductor device according to the present embodiment, the antifuse 10 can be formed by using a damascene process as a normal wiring formation process, which is represented by, e.g., a copper wiring formation process. This achieves a reduction in the number of required steps compared with that of the conventional antifuse formation process, a reduction in cost, and an improvement in yield.

Although the present embodiment has not particularly described the order in which the vias 30a and the trenches 31a are formed, either of the vias 30a and the trenches 31a may be formed earlier.

Although the present embodiment has described the case where the second wire 8 formed above the antifuse 10 is composed of the metal material buried in the via 30 and the trench 31a, the antifuse 10 can also be formed even in the case where only the via 30a is formed without forming the trench 31a and only the via plug is formed above the antifuse 10. In that case, the area required for the formation of the antifuse 10 can be reduced.

In addition, the use of a silicon nitride film (SiN) or silicon carbon (SiC) for the second barrier film 5 in the present embodiment enhances the effect of preventing the diffusion of copper composing the first wire 4. The resultant antifuse 10 allows the setting of the applied voltage which causes a dielectric breakdown to a high value.

It is preferred that, in the antifuse formation region B, the second barrier film 5 has a thickness smaller than that when it was formed first and is therefore lower in level, and the second wire 8 is formed in such a manner as to sink into the portion lower in level. In such a structure, a dielectric breakdown is more likely to occur in the portion of the second barrier film 5 which is lower in level. Accordingly, the antifuse 10 can be used as an antifuse in which a dielectric breakdown is easily caused by the application of a voltage.

Although the present embodiment has described the case where a material used for the wires or via plug is copper, the present invention is also practicable even when a noble metal such as gold or silver is used also as a material instead of copper.

Embodiment 5

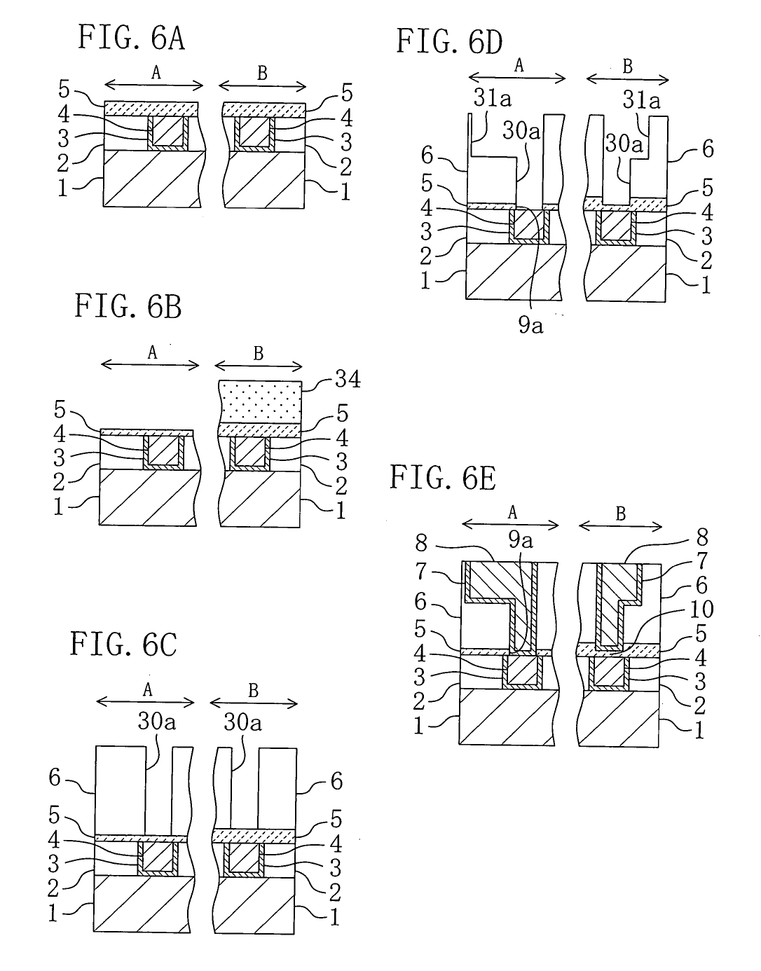

A method for fabricating a semiconductor device having an antifuse structure according to the fifth embodiment of the present invention will be described with reference to FIGS. 6A to 6D.

FIGS. 6A to 6D are cross-sectional views illustrating the principal steps of the method for fabricating a semiconductor device having an antifuse structure according to the fifth embodiment. In FIGS. 6A to 6D, the components common to those shown in FIG. 1 are designated by the same reference numerals.

First, as shown in FIG. 6A, the first insulating film 2 is formed on the semiconductor substrate 1 and then the first wires 4 each made of, e.g., copper and having the first barrier film 3 is formed on the first insulating film 2. Subsequently, the second barrier film 5 is formed over the first insulating film 2 and the first wires 4. The second barrier film 5 functions as a diffusion preventing film for preventing the diffusion of the metal composing the first wires 4 so that it serves herein as a diffusion preventing film against copper. The second barrier film 5 also serves as an etching stopper during the formation of upper-layer vias.

Next, as shown in FIG. 6B, a resist pattern 34 is formed on the portion of the second barrier film 5 located in the antifuse formation region B. By performing etching using the resist pattern 34 as a mask, the portion of the second barrier film 5 located in the circuit formation region A is thinned. Then, the resist pattern 34 is removed.

Next, as shown in FIG. 6C, the second insulating film 6 is formed on the second barrier film 5. Then, the vias 30a are formed in the second insulating film 6. Alternatively, the second insulating film 6 may also be formed as a plurality of layers of different types. It is also possible to perform a planarization process using a CMP technology or the like if a process for reducing a level difference is required as in the case of, e.g., forming an insulating film over an underlying wire.

Next, as shown in FIG. 6D, trenches 31a are formed by etching the second insulating film 6. In this case, since the portion of the second barrier film 5 located in the circuit formation region A has been thinned, the portion of the second barrier film 5 exposed at the bottom portion of the via 30a is removed completely by etching so that the connection hole 9a is formed in the second insulating film 5 and the via 30a reaches the first wire 4. On the other hand, the portion of the second barrier film 5 located in the antifuse formation region B has a large thickness so that, even when the second barrier film 5 exposed at the bottom portion of the via 30a is removed by etching, the via 30a does not reach the first wire 4.

Next, as shown in FIG. 6E, the second wire (metal pattern) 8 made of, e.g., copper and having the third barrier film 7 is formed in each of the connection hole 9a, the via 30a, and the trench 31a in the circuit formation region A, while it is formed in each of the via 30a and the trench 31a in the antifuse formation region B. The second wire 8 can be formed by burying a metal material (which is, e.g., copper herein) by using a sputtering, CVD, or plating technology or the like and then removing the unwanted portion thereof by using a CMP technology.

Since no connection hole is thus provided in the second barrier film 5 in the antifuse formation region B, the second wire 8 having the third barrier film 7 has the second barrier film 5 interposed between itself and the first wire 4 with the first barrier film 3. That is, in the antifuse formation region B, the antifuse 10 is formed in the second barrier film 5 as a film for preventing the diffusion of copper composing the first wire 4, which is located in a layer underlying the second wire 8 not to be connected to the first wire 4.

Thus, according to the embodiment of the present invention, the antifuse 10 can be formed by using a damascene process as a normal wiring formation process, which is represented by, e.g., a copper wiring formation process. This achieves a reduction in the number of required steps compared with that of the conventional antifuse formation process, a reduction in cost, and an improvement in yield.

Although the present embodiment has not particularly described the order in which the vias 30a and the trenches 31a are formed, either of the vias 30a and the trenches 31a may be formed earlier.

Although the present embodiment has described the case where the second wire 8 formed above the antifuse 10 is composed of the metal material buried in the via 30 and the trench 31a, the antifuse 10 can also be formed even in the case where only the via 30a is formed without forming the trench 31a and only the via plug is formed above the antifuse 10. In that case, the antifuse formation region B can be reduced.

In addition, the use of a silicon nitride film (SiN) or silicon carbon (SiC) for the second barrier film 5 in the present embodiment enhances the effect of preventing the diffusion of copper composing the first wire 4. The resultant antifuse 10 allows the setting of the applied voltage which causes a dielectric breakdown to a high value.

It is preferred that, in the antifuse formation region B, the second barrier film 5 has a thickness smaller than that when it was formed first and is therefore lower in level, and the second wire 8 is formed in such a manner as to sink into the portion lower in level. In such a structure, a dielectric breakdown is more likely to occur in the portion of the second barrier film 5 which is lower in level. Accordingly, the antifuse 10 can be used as an antifuse in which a dielectric breakdown is easily caused by the application of a voltage.

Although the present embodiment has described the case where a material used for the wires or via plug is copper, the present invention is also practicable even when a noble metal such as gold or silver is used also as a material instead of copper.

Embodiment 6

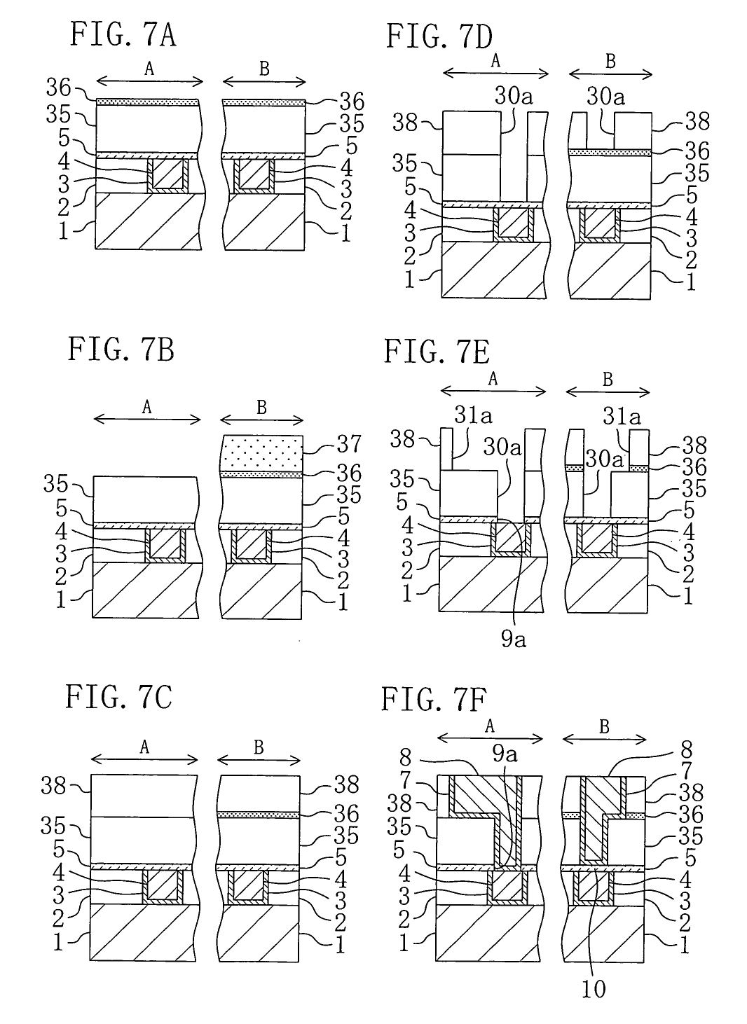

A method for fabricating a semiconductor device having an antifuse structure according to the sixth embodiment of the present invention will be described with reference to FIGS. 7A to 7F.

FIGS. 7A to 7F are cross-sectional views illustrating the principal steps of the method for fabricating a semiconductor device having an antifuse structure according to the sixth embodiment. In FIGS. 7A to 7F, the components common to those shown in FIG. 1 are designated by the same reference numerals.

First, as shown in FIG. 7A, the first insulating film 2 is formed on the semiconductor substrate 1 and then the first wires 4 each made of, e.g., copper and having the first barrier film 3 is formed on the first insulating film 2. Subsequently, the second barrier film 5 is formed over the first insulating film 2 and the first wires 4. The second barrier film 5 functions as a diffusion preventing film for preventing the diffusion of the metal composing the first wires 4 so that it serves as a diffusion preventing film against copper. The second barrier film 5 also serves as an etching stopper during the formation of upper-layer vias. Subsequently, a second insulating film 35 and a third insulating film 36 are formed successively on the second barrier film 5.

Next, as shown in FIG. 7B, a resist pattern 37 is formed on the portion of the third insulating film 36 located in the antifuse formation region B. By performing etching using the resist pattern 37 as a mask, the portion of the third insulating film 36 located in the circuit formation region A is etched away. Then, the resist pattern 37 is removed.

Next, as shown in FIG. 7C, a fourth insulating film 38 is formed over the second insulating film 35 in the circuit formation region A and the third insulating film 36 in the antifuse formation region B.

Next, as shown in FIG. 7D, the via 30a is formed in the second and fourth insulating films 35 and 38 in the circuit formation region A to extend therethrough and reach the second barrier film 5, while the via 30a is formed in the fourth insulating film 38 in the antifuse formation region B to extend therethrough and reach the third insulating film 36. In this case, the third insulating film 36 functions as an etching stopper.

Next, as shown in FIG. 7E, trenches 31a are formed by etching the fourth insulating film 38. In this case, the portion of the second barrier film 5 exposed at the bottom portion of the via 30a is removed by etching in the circuit formation region A so that the connection hole 9a is formed in the second insulating film 5 and the via 30a reaches the first wire 4. In the antifuse formation region B, on the other hand, the respective portions of the third and the second insulating films 36 and 35 located therein are removed so that the second barrier film 5 is exposed at the bottom portion of the via 30a.

Next, as shown in FIG. 7F, the second wire (metal pattern) 8 made of, e.g., copper and having the third barrier film 7 is formed in each of the connection hole 9a, the via 30a, and the trench 31a in the circuit formation region A, while it is formed in each of the via 30a and the trench 31a in the antifuse formation region B. The second wire 8 can be formed by burying a metal material (which is, e.g., copper herein) by using a sputtering, CVD, or plating technology or the like and then removing the unwanted portion thereof by using a CMP technology.

Since no connection hole is thus provided in the second barrier film 5 in the antifuse formation region B, the second wire 8 having the third barrier film 7 has the second barrier film 5 interposed between itself and the first wire 4 with the first barrier film 3. That is, in the antifuse formation region B, the antifuse 10 is formed in the second barrier film 5 as a film for preventing the diffusion of copper composing the first wire 4, which is located in a layer underlying the second wire 8 not to be connected to the first wire 4.

Thus, in the method for fabricating the semiconductor device according to the embodiment, the antifuse 10 can be formed by using a damascene process as a normal wiring formation process, which is represented by, e.g., a copper wiring formation process. This achieves a reduction in the number of required steps compared with that of the conventional antifuse formation process, a reduction in cost, and an improvement in yield.

Although the present embodiment has not particularly described the order in which the vias 30a and the trenches 31a are formed, either of the vias 30a and the trenches 31a may be formed earlier.

Although the present embodiment has described the case where the second wire 8 formed above the antifuse 10 is composed of the metal material buried in the via 30 and the trench 31a, the antifuse 10 can also be formed even in the case where only the via 30a is formed without forming the trench 31a and only the via plug is formed above the antifuse 10. In that case, the area required for the formation of the antifuse can be reduced.

In addition, the use of a silicon nitride film (SiN) or silicon carbon (SiC) for the second barrier film 5 in the present embodiment enhances the effect of preventing the diffusion of copper composing the first wire 4. The resultant antifuse 10 allows the setting of the applied voltage which causes a dielectric breakdown to a high value.

It is preferred that, in the antifuse formation region B, the second barrier film 5 has a thickness smaller than that when it was formed first and is therefore lower in level, and the second wire 8 is formed in such a manner as to sink into the portion lower in level. In such a structure, a dielectric breakdown is more likely to occur in the portion of the second barrier film 5 which is lower in level. Accordingly, the antifuse 10 can be used as an antifuse in which a dielectric breakdown is easily caused by the application of a voltage.

Although the present embodiment has described the case where a material used for the wires or via plug is copper, the present invention is also practicable even when a noble metal such as gold or silver is used also as a material instead of copper.

Embodiment 7

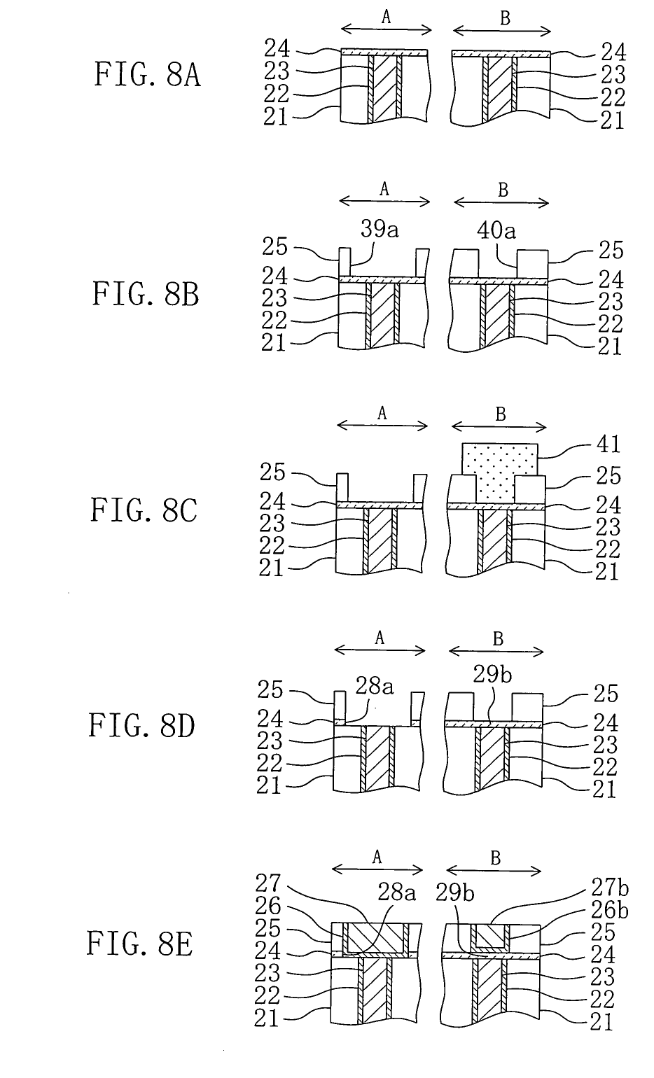

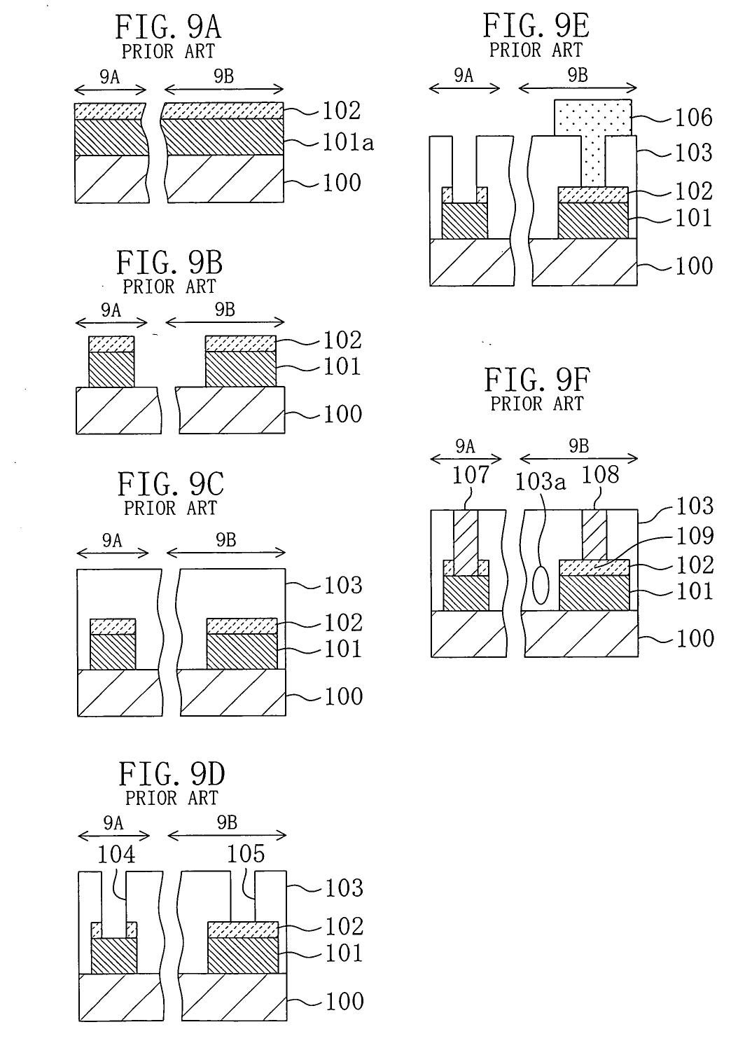

A method for fabricating a semiconductor device having an antifuse structure according to the seventh embodiment of the present invention will be described with reference to FIGS. 8A to 8E.

FIGS. 8A to 8E are cross-sectional views illustrating the principal steps of the method for fabricating a semiconductor device having an antifuse structure according to the seventh embodiment. In FIGS. 8A to 8E, the components common to those shown in FIG. 1 are designated by the same reference numerals.

First, as shown in FIG. 8A, a first insulating film 21 is formed on, e.g., a semiconductor substrate (not shown) and then via plugs 23 each made of, e.g., copper and having a first barrier film 22 is formed on the first insulating film 21. Subsequently, a second barrier film 24 is formed over the first insulating film 21 and the via plugs 23. The second barrier film 24 functions herein as a diffusion preventing film for preventing the diffusion of the metal composing the via plugs 23 so that it serves as a diffusion preventing film against copper. The second barrier film 24 also serves as an etching stopper during the formation of upper-layer vias.

Next, as shown in FIG. 8B, a second insulating film 25 is formed on the second barrier film 24. Then, a trench 39a is formed in the second insulating film 25 in the circuit formation region A, while a via 40a is formed in the second insulating film 25 in the antifuse formation region B.

Next, as shown in FIG. 8C, a resist pattern 41 is formed to cover the via 40a formed in the antifuse formation region B.

Next, as shown in FIG. 8D, etching is performed by using the resist pattern 41 as a mask to remove the portion of the second barrier film 24 exposed at the bottom portion of the trench 39a formed in the circuit formation region A, thereby forming a connection hole 28a and exposing the via plug 23 therein. Then, the resist pattern 41 is removed.

Next, as shown in FIG. 8E, a wire (metal pattern) 27 made of, e.g., copper and having the third barrier film 26 is formed in each of the connection hole 28a and the trench 39a in the circuit formation region A, while a via plug (metal pattern) 27b made of, e.g., copper and having a third barrier film 26b is formed in the via 40a in the antifuse formation region B. The wire 27 and the via plug 27b can be formed by burying a metal material (which is, e.g., copper herein) by using a sputtering, CVD, or plating technology or the like and then removing the unwanted portion thereof by using a CMP technology.

Since no connection hole is thus provided in the second barrier film 24 in the antifuse formation region B, the via plug 27b having the third barrier film 26b has the second barrier film 24 interposed between itself and the via plug 23 with the first barrier film 22. That is, in the antifuse formation region B, the antifuse 29b is formed in the second barrier film 24 as a film for preventing the diffusion of copper composing the via plug 23, which is located in a layer underlying the via plug 27b not to be connected to the via plug 23.

Thus, in the method for fabricating the semiconductor device according to the present embodiment, the antifuse 29b can be formed by using a damascene process as a normal wiring formation process, which is represented by, e.g., a copper wiring formation process. This achieves a reduction in the number of required steps compared with that of the conventional antifuse formation process, a reduction in cost, and an improvement in yield.

Although the present embodiment has described the case where the via plug 27b is formed above the antifuse 29b, it is also possible to adopt a structure in which a wire is formed above the antifuse 29b in the same manner as in the second embodiment shown in FIG. 3. In the present embodiment, the area required for the formation of the antifuse can be reduced compared with that required in the structure of FIG. 3.

In addition, the use of a silicon nitride film (SiN) or silicon carbon (SiC) for the second barrier film 24 in the present embodiment enhances the effect of preventing the diffusion of copper composing the via plug 23. The resultant antifuse 29b allows the setting of the applied voltage which causes a dielectric breakdown to a high value.

It is preferred that, in the antifuse formation region B, the second barrier film 24 has a thickness smaller than that when it was formed first and is therefore lower in level, and the via plug 27b is formed in such a manner as to sink into the portion lower in level. In such a structure, a dielectric breakdown is more likely to occur in the portion of the second barrier film 24 which is lower in level. Accordingly, the antifuse 29b can be used as an antifuse in which a dielectric breakdown is easily caused by the application of a voltage.

Although the present embodiment has described the case where a material used for the wires or via plugs is copper, the present invention is also practicable even when a noble metal such as gold or silver is used also as a material instead of copper.

Thus, the present invention is suitable for a semiconductor device and a fabrication method therefor and particularly suitable for an antifuse structure used in an FPGA (Field Programmable Gate Array) element as a reconfigurable logic device and a fabrication method therefor.

1. A semiconductor device comprising:
a first metal pattern made of a first metal formed on a semiconductor substrate;
an insulating film formed over the first metal pattern; and
a second metal pattern made of a second metal formed on the insulating film, wherein
the insulating film has a barrier property for preventing diffusion of the first metal.

2. The semiconductor device of claim 1, wherein the insulating film contains the diffused first metal.

3. The semiconductor device of claim 1, wherein the second metal pattern is formed in such a manner as to sink into the insulating film.

4. The semiconductor device of claim 1, wherein the first metal pattern is a wire or a via plug.

5. The semiconductor device of claim 1, wherein the second metal pattern is a wire or a via plug.

6. A semiconductor device comprising:
a first metal pattern made of a first metal formed on a semiconductor substrate;
an insulating film formed over the first metal pattern; and
a second metal pattern made of a second metal formed on the insulating film, wherein
the insulating film has a barrier property for preventing diffusion of the first metal and
the second metal pattern is formed in a circuit formation region to extend through the insulating film and be electrically connected to the first metal pattern, while it is formed in an antifuse formation region with the insulating film being interposed between itself and the first metal pattern.

7. The semiconductor device of claim 6, wherein the insulating film contains the diffused first metal.

8. The semiconductor device of claim 6, wherein the second metal pattern in the antifuse formation region is formed in such a manner as to sink into the insulating film.

9. The semiconductor device of claim 6, wherein the first metal pattern is a wire or a via plug.

10. The semiconductor device of claim 6, wherein the second metal pattern is a wire or a via plug.

11. A method for fabricating a semiconductor device, the method comprising the steps of:
forming a wire made of a first metal on a semiconductor substrate;
forming a first insulating film over the wire;
forming a second insulating film on the first insulating film;
forming an opening for exposing the first insulating film in each of respective portions of the second insulating film located in a circuit formation region and in an antifuse formation region such that the opening is positioned above the wire;
after forming a resist pattern such that the opening in the antifuse formation region is covered therewith, performing etching by using the resist pattern as a mask to remove a portion of the first insulating film exposed at a bottom portion of the opening in the circuit formation region and thereby expose the wire; and
after removing the resist pattern, burying a second metal in each of the opening in the circuit formation region and the opening in the antifuse formation region to form a metal pattern, wherein
the first insulating film has a barrier property for preventing diffusion of the first metal.

12. A method for fabricating a semiconductor device, the method comprising the steps of:
forming a wire made of a first metal on a semiconductor substrate;
forming a first insulating film over the wire;
forming a second insulating film on the first insulating film;
forming a first opening for exposing the first insulating film in each of respective portions of the second insulating film located in a circuit formation region and in an antifuse formation region such that the opening is positioned above the wire;
in forming a resist pattern composed of a positive resist for forming a second opening over the first opening in the antifuse formation region, performing etching by using a remaining portion of the positive resist formed by insufficient exposure as a mask to remove a portion of the first insulating film exposed at a bottom portion of the first opening in the circuit formation region and thereby expose the wire; and
after removing the resist pattern, burying a second metal in each of the first opening in the circuit formation region and the first opening in the antifuse formation region to form a metal pattern, wherein
the first insulating film has a barrier property for preventing diffusion of the first metal.

13. A method for fabricating a semiconductor device, the method comprising the steps of:
forming a wire made of a first metal on a semiconductor substrate;
forming a first insulating film over the wire;
performing etching to thin a portion of the first insulating film located in a circuit formation region;
after the step of performing the etching, forming a second insulating film on the first insulating film;
forming an opening for exposing the wire in a portion of the second insulating film located in the circuit formation region such that the opening is positioned above the wire, while forming an opening for exposing the first insulating film in a portion of the second insulating film located in an antifuse formation region such that the opening is positioned above the wire; and
burying a second metal in each of the opening in the circuit formation region and the opening in the antifuse formation region to form a metal pattern, wherein
the first insulating film has a barrier property for preventing diffusion of the first metal.

14. A method for fabricating a semiconductor device, the method comprising the steps of:
forming a wire made of a first metal on a semiconductor substrate;
forming a first insulating film over the wire;
forming a second insulating film on the first insulating film;
forming a third insulating film on the second insulating film;
performing etching to remove a portion of the third insulating film located in a circuit formation region;
after the step of performing the etching, forming a fourth insulating film over the second and third insulating films;
forming an opening for exposing the wire in each of respective portions of the fourth, second, and first insulating films located in the circuit formation region such that the opening is positioned above the wire, while forming an opening for exposing the first insulating film in each of respective portions of the fourth, third, and second insulating films located in the antifuse formation region such that the opening is positioned above the wire; and
burying a second metal in each of the opening in the circuit formation region and the opening in the antifuse formation region to form a metal pattern, wherein
the first insulating film has a barrier property for preventing diffusion of the first metal.

15. The method of any one of claims 11 to 14, wherein
the step of forming the opening is a step of forming a wiring trench or a via hole and
the step of forming the metal pattern is a step of forming a wire if the wiring trench is formed in the step of forming the opening, while it is a step of forming a via plug if the via hole is formed in the step of forming the opening.

16. A method for fabricating a semiconductor device, the method comprising the steps of:
forming a via plug made of a first metal on a semiconductor substrate;
forming a first insulating film over the via plug;
forming a second insulating film on the first insulating film;
forming an opening for exposing the first insulating film in each of respective portions of the second insulating film located in a circuit formation region and in an antifuse formation region such that the opening is positioned above the via plug;
after forming a resist pattern such that the opening formed in the antifuse formation region is covered therewith, performing etching by using the resist pattern as a mask to remove a portion of the first insulating film exposed at a bottom portion of the opening in the circuit formation region and thereby expose the via plug; and
after removing the resist pattern, burying a second metal in each of the opening in the circuit formation region and the opening in the antifuse formation region to form a metal pattern, wherein
the first insulating film has a barrier property for preventing diffusion of the first metal.

17. The method of claims 16, wherein
the step of forming the opening is a step of forming a wiring trench or a via hole and
the step of forming the metal pattern is a step of forming a wire if the wiring trench is formed in the step of forming the opening, while it is a step of forming a via plug if the via hole is formed in the step of forming the opening.

18. The method of claim 11, 12, 13, 14, or 16, wherein the first insulating film contains the diffused first metal.

19. The method of claim 11, 12, 13, 14, or 16, wherein the metal pattern formed on the first insulating film is formed in such a manner as to sink into the insulating film.
